(19) United States
(12) Patent Application Publication
(10) Pub. No.: US 2009/0211624 A1
(43) Pub. Date: Aug. 27, 2009

(54) Solar powered spa and hot tub down light sconce

(76) Inventor: Michael C. Genova, Spokane, WA (US)

Correspondence Address: Gregory IPL, P.C., 601 W. Main, Suite 904, SPOKANE, WA, 99201-3825, US

(21) Appl. No.: 12/072,616

(22) Filed: Feb. 26, 2008

(51) Int. Cl. H01L 31/042

(52) U.S. Cl. 136/251

(57) ABSTRACT

An apparatus includes a solar-powered lighting system supported by a wedge-shaped housing. The housing has a back, an upper side and a lower side. The back is adapted to be mounted against a supporting surface such as a wall or the like. The upper side is adapted to support a solar panel. The lower side is adapted allow light to be projected through it.

### TECHNICAL FIELD

The technical field of the inventions relates to apparatus and methods for providing solar powered lighting.

### BACKGROUND OF THE INVENTION

Electric lighting has traditionally been provided by drawing power from large, commercial electrical power systems such as the national grid, or from batteries, or from motor-driven generators. Historically, nearly all such power is ultimately produced from the combustion of fossil fuels, including fuel oil, natural gas, and coal. In recent times, the demand for, and thus the cost of, these fossil fuels has been increasing at a relatively high rate. The cost of traditionally powered electric lighting has thus experienced an associated increase. Moreover, so-called greenhouse gas emission resulting from fossil fuel combustion is becoming the subject of increasing concern.

Furthermore, the use of lighting that draws power from a grid or from a motor-driven generator requires the installation and maintenance of a wiring system to carry and distribute the electrical power. Alternatively, the use of battery powered lighting requires periodic replacement and/or recharging of the battery power supply.

Some or all of the problems explained above and other problems may be helped or solved by the inventions shown and described herein. Such inventions may also be used to address other problems not set out above or which are developed at a later time. The future may also bring to light unknown benefits which may be in the future appreciated from the novel inventions shown and described herein.

### BRIEF DESCRIPTION OF THE DRAWINGS

Preferred forms, configurations, embodiments and/or diagrams relating to and helping to describe preferred versions of the inventions are explained and characterized herein, often with reference to the accompanying drawings. The drawings and all features shown therein also serve as part of the disclosure of the inventions of the current application whether described in text or merely by graphical disclosure alone. Such drawings are briefly described below.

FIG. 1 is a perspective view showing a geometric object.

FIG. 2 is a front perspective view showing an apparatus in accordance with an embodiment of the present disclosure.

FIG. 3 is a rear perspective view showing the apparatus depicted in FIG. 2.

FIG. 4 is an exploded view of the apparatus depicted in FIG. 2.

FIG. 5 is a front view of the apparatus depicted in FIG. 2.

FIG. 6 a rear view of the apparatus depicted in FIG. 2.

FIG. 7 is a top view of the apparatus depicted in FIG. 2.

FIG. 8 is a bottom view of the apparatus depicted in FIG. 2.

FIG. 9 is a side view of the apparatus depicted in FIG. 2.

### DETAILED DESCRIPTION OF THE PREFERRED EMBODIMENTS

### Table Listing Subsections of Detailed Description

A table of subsections for the detailed description is below.

Table of Subsections

Table Listing Subsections of Detailed Description
Introductory Notes
Preliminary Geometric Concepts
General Configuration of the Apparatus
Operational System and Components
Photo Sensor
Solar Panel
Light Source
Storage Device
Control Device
Chassis
Housing
Operation, Methods and Manner of Use
Interpretation Notes

### Introductory Notes

The readers of this document should understand that the embodiments described herein may rely on terminology used in any section of this document and other terms readily apparent from the drawings and the language common therefor as may be known in a particular art and such as known or indicated and provided by dictionaries. Dictionaries were used in the preparation of this document. Widely known and used in the preparation hereof are Webster's Third New International Dictionary (©1993), The Oxford English Dictionary (Second Edition, ©1989), and The New Century Dictionary (©2001-2005), all of which are hereby incorporated by reference for interpretation of terms used herein and for application and use of words defined in such references to more adequately or aptly describe various features, aspects and concepts shown or otherwise described herein using more appropriate words having meanings applicable to such features, aspects and concepts.

This document is premised upon using one or more terms with one embodiment that may also apply to other embodiments for similar structures, functions, features and aspects of the invention. Wording used in the claims is also descriptive of the invention and the text of both claims and abstract are incorporated by reference into the description entirely in the form as originally filed. Terminology used with one, some or all embodiments may be used for describing and defining the technology and exclusive rights associated herewith.

The readers of this document should further understand that the embodiments described herein may rely on terminology and features used in any section or embodiment shown in this document and other terms readily apparent from the drawings and language common or proper therefor. This document is premised upon using one or more terms or features shown in one embodiment that may also apply to or be combined with other embodiments for similar structures, functions, features and aspects of the invention and provide additional embodiments of the inventions.

### Preliminary Geometric Concepts

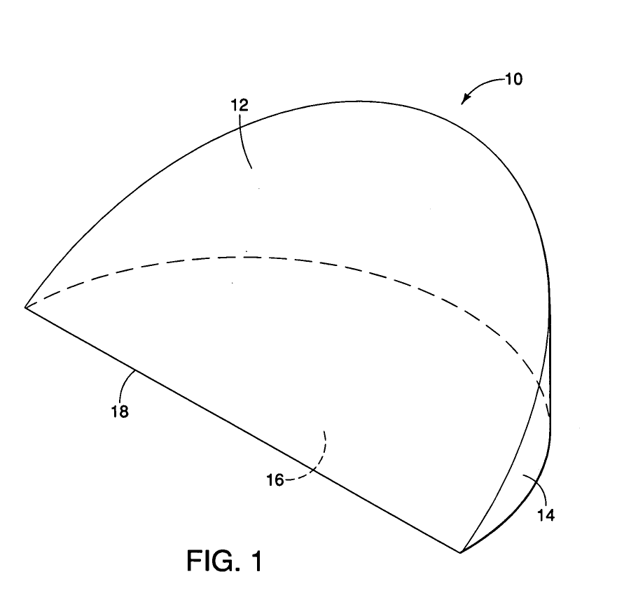

FIG. 1 is a perspective view showing a geometric object 10, the study of which is relevant to the understanding of one or more features or aspects of at least one invention described herein. From a study of FIG. 1, it is apparent that the geometric object 10 can be described as a wedge. Alternatively, the geometric object 10 can be described as wedge-shaped. In more specific terms the geometric object 10, as depicted, can be described as a cylindrical wedge. A cylindrical wedge can be formed by a cylinder and two planes, all of which intersect each other.

In terms known to those in the art of geometry, the cylindrical wedge 10 is defined by a generalized cylinder (also known as a cylindrical surface) 14, a planar base 16 that intersects the generalized cylinder, and a planar tongue 12 that intersects both the generalized cylinder and the base. The base 16 and the tongue 12 can intersect to form an edge 18. Generally, the wedge 10 can be described as being three-sided because the tongue, the generalized cylinder 14, and the base 16 together make up and/or define the whole of the object.

As is specifically depicted in FIG. 1 for illustrative purposes, the base 16 can have the form and/or the shape of a semicircle. Moreover, the base 16 and can be perpendicular to the generalized cylinder 14. In such an instance wherein the base is substantially perpendicular to the generalized cylinder, the geometric object 10 can be referred to as a right circular cylindrical wedge. Moreover, in the case of a right circular cylindrical wedge, the tongue 12 is substantially semi-elliptical in shape.

Although the geometric object 10 is illustratively depicted and/or described herein as a right circular cylindrical wedge, it is to be understood for the purposes of this discussion that the term wedge does not necessarily denote a cylindrical wedge, and that the term cylindrical wedge does not necessarily denote a right circular cylindrical wedge. Furthermore, it is to be understood for the purposes of this discussion that the terms, generalized cylinder 14, base 16, and tongue 12, do not necessarily imply, suggest, or require any specific shape or specific orientation relative to each other.

### General Configuration of the Apparatus

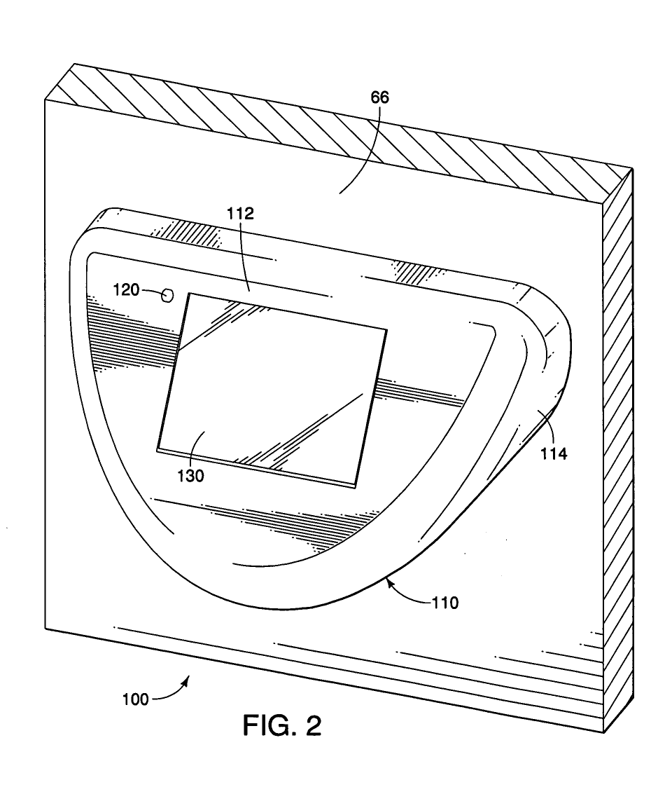

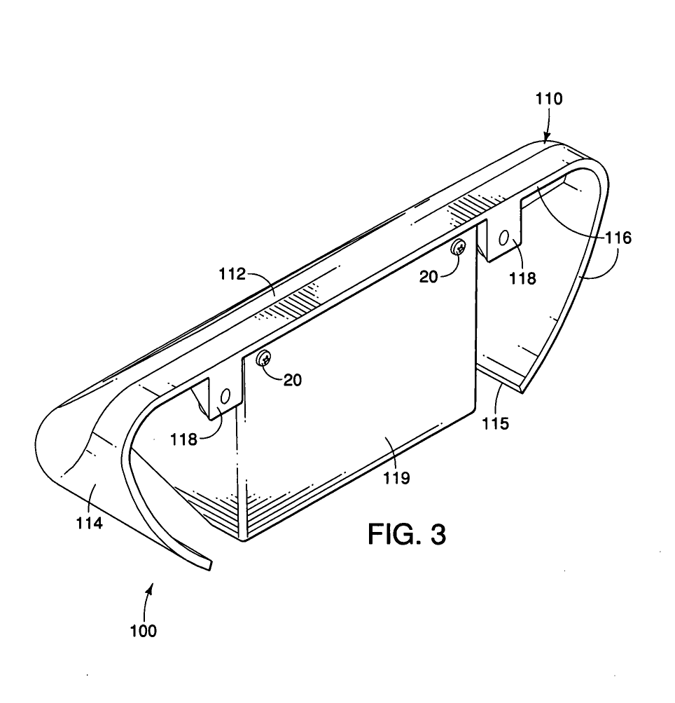

FIG. 2 is a front perspective vew in which an apparatus 100 is depicted in accordance with one embodiment of the disclosure. The apparatus 100 is adapted to be mounted on and/or supported by a surface 66. FIG. 3 is a rear perspective view of the apparatus 100 depicted in FIG. 2. It is to be understood that the surface 66 (shown in FIG. 2) has been omitted from FIG. 3 for clarity. The apparatus 100 can be adapted to be employed as a self-contained, solar powered lighting fixture as is more fully described herein below. The apparatus 100 is intended to be mounted or supported generally in the orientation depicted in FIG. 1.

The apparatus 100 can be adapted to project visible light or illumination 77 through a lower side 114 of the housing 110. The illumination 77 can be, for example, substantially in the form of white light. The projection of the light 77 from the apparatus 100 enables the apparatus to be employed to provide lighting or illumination at night or at other times of darkness. In accordance with at least one embodiment of the present disclosure, the light 77 can be projected through an opening 115 defined in the lower side 114 of the housing 110.

The support surface 66 can be defined by a wall, a panel, a bulkhead, or the like (none of which are specifically depicted). The surface 66 can be substantially flat and vertical, as is generally depicted. However, it is to be understood that the surface 66 can have any of a number of shapes, contours, profiles or orientations. The surface 66 can be one that is exposed to solar energy either directly or indirectly. In other words, the surface 66 can be one that is exposed to solar radiation such as daylight, which include, but need not necessarily include, direct sunlight. By way of example only, the surface 66 can be a wall or panel of a spa, a hot tub, or the like.

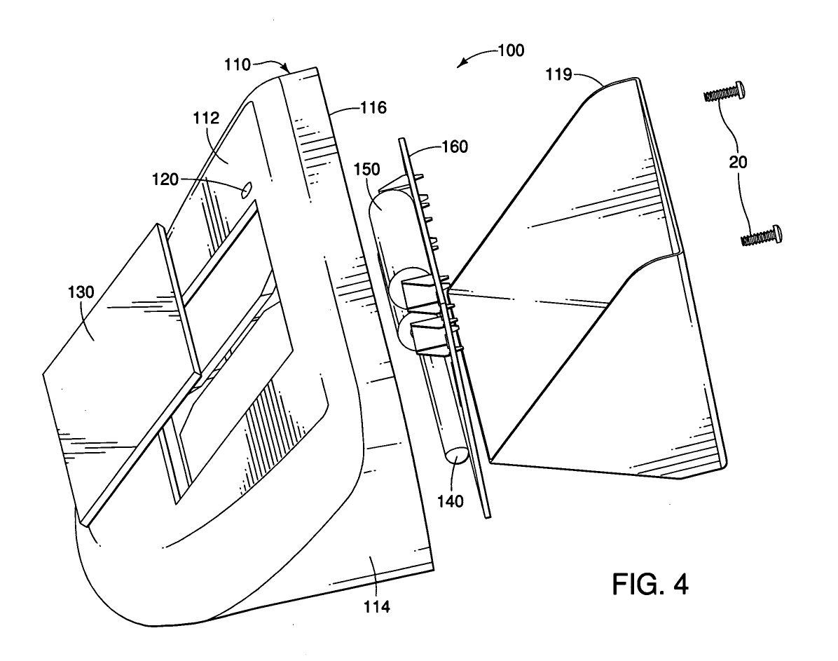

FIG. 4 is an exploded view of the apparatus 100 depicted in FIGS. 2 and 3. A study of FIG. 4 reveals that the apparatus 100 includes a wedge-shaped housing 110. The housing 110 supports a lighting system or operational system that is made up of one or more operational components including but not limited to a photosensor 120, a solar panel 130, a chassis 119, a light source 140, a storage device 150, and a control device 160, all of which are discussed in greater detail herein below.

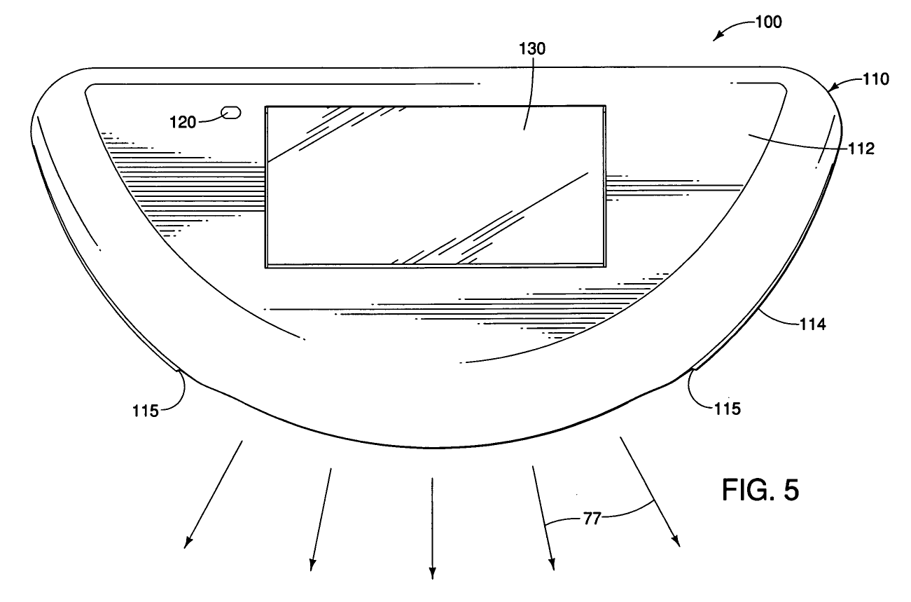

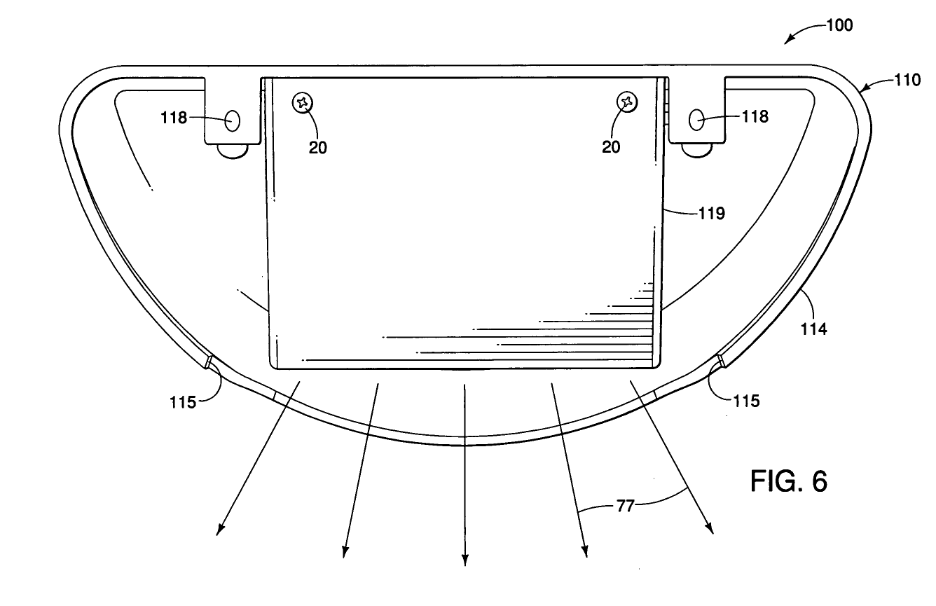

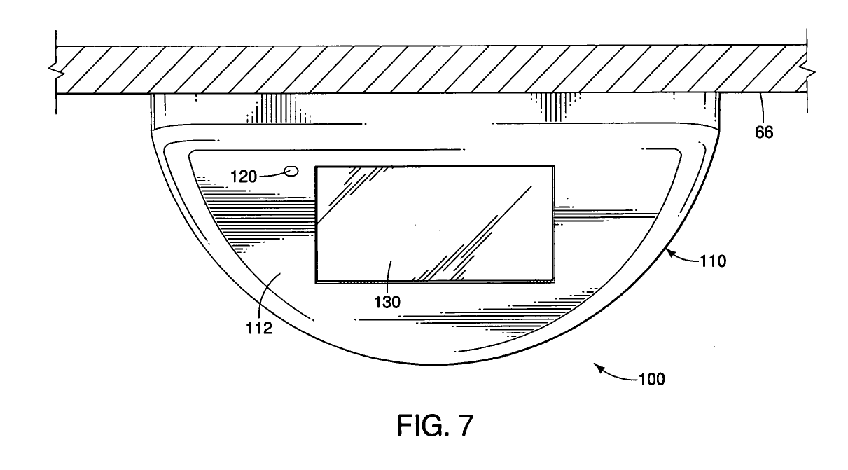

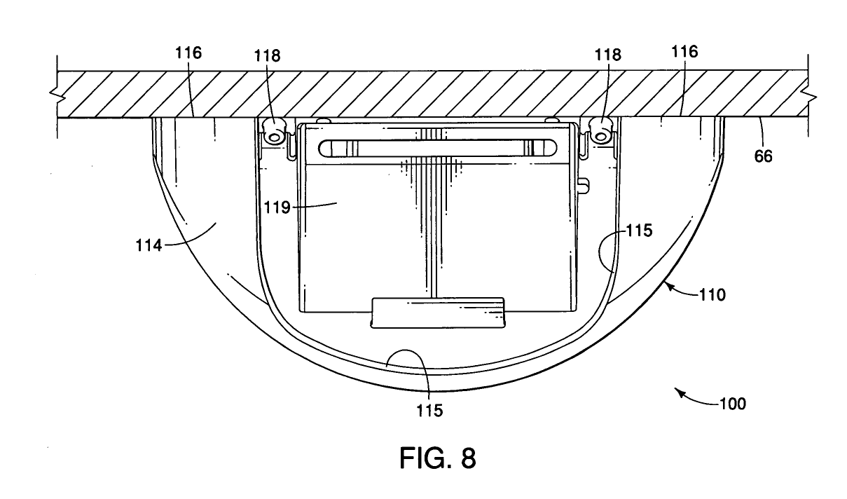

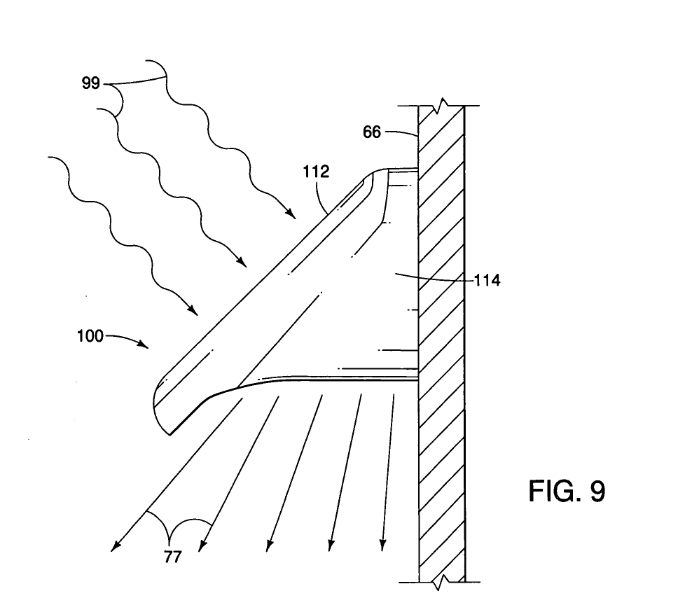

In addition to FIGS. 1-4 discussed above, an additional series of views of the apparatus 100 is provided to facilitate greater understanding of one or more aspects or features of at least one invention described herein. This additional series of views of the apparatus 100 includes: FIG. 5, which is a front view; FIG. 6, which is a rear view; FIG. 7, which is a top view; FIG. 8, which is a bottom view; and FIG. 9, which is a side view. For clarity, the surface 66 (shown in FIG. 2) has been omitted from each of FIGS. 5 and 6.

### Operational System and Components

Each of the photosensor 120, the solar panel 130, the light source 140, the electrical storage device 150, and the control device 160 can be referred to as an operational component. Each of the operational components 120, 130, 140, 150, 160 is adapted to work in concert with at least one other operational component to produce light 77 for illumination and the like. Two or more operational components 120, 130, 140, 150, 160 that operate or perform in cooperation with one another can be referred to as a the lighting system or the operational system. Thus, a lighting system or an operational system in accordance with at least one embodiment of the disclosure includes two or more of the photosensor 120, the solar panel 130, the light source 140, the electrical storage device 150, and the control device 160.

### Photo Sensor

The photosensor 120 is adapted to detect presence of a predetermined level of ambient light. By way of example only, the photosensor 120 is adapted to detect a predetermined level of natural light such as daylight. In accordance with one embodiment of the present disclosure, the photosensor 120 is adapted to generate and/or transmit a data signal that differentiates between ambient light above a predetermined level and ambient light below the predetermined level. The photosensor 120 can be configured to generate a signal when ambient light falls, or is, below a predetermined level. For example, the photosensor 120 can be adapted to generate a signal when ambient light rises, or is, above a predetermined level. The photosensor 120 can be any of a number of possible types and/or can have any of a number of possible configurations.

### Solar Panel

The solar panel 130 is adapted to produce electrical energy from solar energy or solar radiation. In other words, the solar panel 130 is adapted to convert solar energy or power to electrical energy or power. Solar energy or power can be, for example, in the form of daylight or other such solar radiation. The solar panel 130 can be any of a number of various types and/or can have any of a number of possible configurations or forms. By way of example only, the solar panel 130 can include at least one photovoltaic silicon cell for generating electrical power from solar power. Moreover, the solar panel 130 can have any of a number possible shapes, contours, profiles or orientations and the like. Specifically, the exemplary solar panel 130 can be substantially flat and rectangular. However, it is to be understood that many other shapes, contours and profiles of the solar panel 130 are possible including those of a cylindrically curved surface or a compound curve.

### Light Source

The light source 140 is adapted to produce illumination or light 77, such as visible light, from electrical energy or power. In accordance with one embodiment of the present disclosure, the light source 140 is adapted to produce illumination substantially in the form of white light. However, the light source 140 can be adapted in accordance with at least one alternative embodiment of the disclosure to produce illumination 77 that is not white light. For example, the light 77 can be substantially red light. By way of further example, the light 77 can be substantially blue light. The light 77 can be employed for general illumination of an area such as a walkway, a patio, or other such area surrounding a spa, or the like.

The light source 140 can be any of a number of various types and/or can have any of a number of possible configurations. Specifically, the light source 140 can include a light emitting diode (“LED”) adapted to produce light from electrical energy or power. Alternatively, the light source 140 can include a light bulb such as an incandescent or florescent light bulb. It is to be understood that the light source 140 can additionally and/or alternatively include other types of devices not specifically described or depicted herein such as filters, reflectors, lenses, diffusers, and the like.

### Storage Device

The storage device 150 is adapted to store electrical energy to be used by the light source 140 for producing light 77. The storage device 150 can be any of a number of various types and/or can have any of a number of possible configurations. By way of example, the storage device 150 can include or can be substantially in the form of at least one battery. By way of further example, the storage device 150 can include or can be substantially in the form of at least one capacitor. The storage device 150 can be adapted to receive and store energy or power generated by the solar panel 130. However, it is to be understood that it is not required that the storage device be adapted to receive and store energy or power generated by the solar panel 130. For example, the storage device 150 can include or be substantially in the form of a conventional replaceable non-rechargeable battery. Alternatively, the storage device 150 can be adapted to be receive and/or store energy or power from an external power supply or the like.

### Control Device

The control device 160 is adapted to facilitate production of light 77 by cooperative operation of two or more other operational components such as the sensor 120, the solar panel 130, the light source 140, and the storage device 150. The control device 160 can be any of a number of various types and/or can have any of a number of possible configurations. For example, the control device 160 can be substantially in the form of a circuit board or the like. By way of further example, the control device 160 can be substantially in the form of, or can include, one or more switches and/or relays. By way of still further example, the control device 160 can include or can be in the form of a processor or the like.

The control device 160 can include one or more various linking means or devices for data and/or power transmission. Such linking means or devices can include, for example, electrical wires, electronic cables, and the like. Accordingly, the control device 160 can serve to link, or can be linked with, one or more of the other operational components 120, 130, 140, 150 for transmission of signals and/or power there between. For example, the photosensor 120, the light source 140, and the storage device 150 can be linked to the control device 160. Thus, when the photosensor 120 detects ambient light below a predetermined level, the control device 160 in response can allow the light source 140 to draw power from the storage device 150 to thus project light 77.

In accordance with at least one embodiment of the present disclosure, the photosensor 120 can detect a level of ambient light relative to a predetermined level. The control device 160, in response to the detection by the photosensor 120 of a level of ambient light, can control activation of the light source 140 by controlling flow of electrical power from the storage device 150 to the light source. Accordingly, the control device 160 can include or can be substantially in the form of a switch and/or a relay that controls an electrical power connection between the storage device 150 and the light source 140.

### Chassis

The chassis 119 can be employed to enclose and/or support one or more operational components such as the sensor 120, the solar panel 130, the light source 140, the storage device 150, and the controller 160. The chassis 119 can be integral with the housing 110. However, it is not required that the chassis 119 be integral with the housing 110. The chassis 119 can be substantially in the form of an enclosure as is depicted. The chassis 119 can be attached to the housing 110 by way of an attachment means, which can include, for example, one or more fasteners 20, or the like.

In accordance with at least one embodiment of the disclosure, the light source 140 is enclosed within the chassis 119. Accordingly, at least a portion of the chassis 119, such as the lower portion thereof, can be substantially transparent, or at least translucent, in order to allow the light 77 to be projected from the light source 140 and through the chassis in the manner sufficient to provide the desired illumination. Alternatively, if the light source 140 is located within the chassis 119, at least a portion of the chassis can be open to allow light or illumination to be projected there through.

### Housing

Recalling the discussion herein above with respect to FIG. 1, it will be appreciated from a study of FIGS. 1-9 that the housing 110 can be substantially wedge-shaped. More specifically, the housing 110, as is illustratively depicted in FIGS. 2-9 can be shaped substantially like the geometric object 10 shown in FIG. 1, and which can be described as a wedge, and more particularly as a cylindrical wedge.

One difference between the geometric object 10 and the housing 110 in accordance with one embodiment of the disclosure is that the housing is depicted as having substantially rounded, or softened, corners and edges, while the edges and corners of the geometric object are depicted as being sharp. However, it is to be understood that depiction of the housing 110 with rounded, or softened, corners and edges is exemplary only, and housings having any of a range of sharp to round corners and/or edges from round to sharp are included within the scope of one or more inventions disclosed herein.

In accordance with at least one embodiment of the disclosure, the housing 110 can be described as being three-sided. Accordingly, the housing 110 can have a first side 112, a second side 114 and a third side 116 that make up substantially the whole of the housing. The first side 112 can also be called the upper side because it is adapted to be facing in a generally upward orientation when the apparatus 100 is mounted to the surface 66. The second side 114 can also be called the lower side because it is adapted to be facing in a substantially downward orientation when the apparatus 100 is mounted to the surface 66. Likewise, the third side 116 can also be called the back because it adapted to be located substantially against the surface 66 when the apparatus 100 is mounted thereto.

Recalling again the discussion above with respect to FIG. 1, the geometric object 10 has been described as a wedge, and more specifically as a right circular cylindrical wedge. It will be appreciated from a close study of FIGS. 1-9 that in accordance with at least one embodiment of the present disclosure, the housing 110 can be shaped substantially like a cylindrical wedge. In more specific terms, the housing 110 can be shaped substantially like a right circular cylindrical wedge.

When describing the housing 110 as having a wedge shape similar to that of the geometric object 10, it will be appreciated that the back, or rear side, 116 of the housing can be described as corresponding to the base 16 of the geometric object. More specifically, when the geometric object 10 is oriented so that the edge 18 is at the top or is facing upward, and when the object 10 and the housing are placed side-by-side, then it is evident that the back 116 of the housing 110 corresponds to the base 16 of the object 10. Similarly, the lower side 114 of the housing 110 can be described as corresponding to the generalized cylinder 14 of the geometric object 10. Likewise, the upper side 112 of the housing 110 can be described as corresponding to the tongue 12 of the geometric object 10.

The housing 110 can be fabricated from any of a number of materials including any of a number of suitable plastics, resin, metal, and the like. Furthermore, the housing 110 can be fabricated using any of a number of possible manufacturing and/or fabrication techniques and/or methods. For example, in accordance with one embodiment of the present disclosure, the housing 110 can be fabricated from a plastic material using an injection molding and/or forming technique.

The upper side 112 of the housing 110 can be substantially planar and/or flat. The upper side 112 is intended to face generally upwardly when the apparatus 100 is mounted to the surface 66. However, housing 110 can be configured such that the upper side 112 is substantially flat, but is not level. More specifically, the housing 110 can be configured such that the upper side 112 is sloped or angled when the apparatus 100 is supported on the surface 66. Thus, the upper side 112 can be obliquely oriented relative to the back 116 and/or relative to the surface 66 when the apparatus 100 is supported thereon.

The lower side 114 of the housing 110 can be at least partially open to allow light or illumination 77 to be projected through the lower side. For example, the lower side 114 can define therein an opening 115. Alternatively, at least a portion of the lower side 114 can be transparent or at least translucent to enable the passage of light 77 there through. In accordance with at least one embodiment of the disclosure, at least a portion of the lower side 114 can be substantially in the form of a lense or the like to facilitate transmission, dispersion, and/or projection of light 77 through the lower side.

The lower side 114 can have a curved or circular shape. More specifically, the lower side 114 can be substantially cylindrical as is depicted. However, it is to be understood that the lower side 114 can have any of a number of other possible shapes and/or contours such as that of a partial sphere. By way of further example, the lower side 114 can be multi-faceted. Specifically, in accordance with at least one alternative embodiment not depicted, the lower side 114 can include a plurality of substantially flat facets joined together to form substantially the whole of the lower side.

The back 116 of the housing 110 can be substantially planar and/or flat. The upper side 112 and the back 116 can be obliquely oriented, or inclined, relative to each other. The lower side 114 can be substantially perpendicular to the back 116. It is to be understood that the back 116 is illustratively depicted as being substantially flat for mounting against a substantially flat surface 66. However, it is to be understood that the back 116 can have any of a number of other possible shapes and/or contours.

In accordance with one embodiment of the disclosure, the back 116 can have a shape or contour that is suited for mounting against a surface 66 having a corresponding or complimentary shape or contour. For example, if the apparatus 100 is intended to be mounted on a surface 66 that is curved, then the back 116 can be formed to have a complimentary curvature to facilitate substantially parallel juxtaposition of the back against the surface. Similarly for example, if the apparatus 100 is intended to be mounted on a surface 66 that is multi-faceted, then the back 116 can correspondingly multi-faceted to facilitate substantially parallel juxtaposition of the back against the surface.

As is revealed from a study of FIG. 3, the back 116 need not be solid and/or continuous. Specifically, for example, the back 116 can be at least partially open and/or can have a discontinuous perimeter. This can result in conservation of material in the manufacture of the housing 110 and can also provide for easier access to the internal components of the housing. However, alternatively, the back 116 can be at least substantially solid or closed. In accordance with in accordance with a further alternative embodiment of the disclosure, the back can include a removable panel or door (not shown).

With continued reference to FIG. 3, the housing 110 can define various mounting features 118. The mounting features 118 can have any of a number of possible forms or variations. For example, as is specifically depicted, the mounting features 118 can be in the form of a tab or boss or the like that defines a hole through which a fastener (not shown) such as a screw or the like can be passed to mount and/or attach the apparatus 100 to the surface 66. A study of FIG. 8 reveals that, in accordance with at least one embodiment of the disclosure, the mounting features 118 are accessible through the opening 115 defined in the lower side 114.

### Operation, Methods and Manner of Use

In accordance with one embodiment of the present disclosure, a method or manner of use includes mounting, fastening or otherwise attaching the apparatus 100 to a supporting surface 66. The surface 66 can be substantially flat and substantially vertical as depicted in the accompanying figures. By way of example, the surface 66 can be defined on a wall, a door, a panel, a bulkhead or the like. However, the surface 66 upon which the apparatus is to be mounted or supported can have any of a number of possible shapes, contours or orientations. The apparatus 100 can be mounted or attached to the surface 66 by way of the mounting feature 118 described above.

The apparatus 100 can be mounted on the surface 66 in a location, position, or orientation that allows solar energy or radiation 99 to impinge upon the solar panel 130. The solar energy 99 can be substantially in the form of direct sunlight or indirect, reflected sunlight. When the apparatus 100 is mounted on a substantially vertical surface 66 as depicted, the lower side 114 can be generally facing downward. In this manner, the light 77 can be projected substantially downwardly from the lower side 114.

In accordance with at least one embodiment of the disclosure, the apparatus 100 can be described as self activating because no further action is generally required for operation of the apparatus other than mounting the apparatus to the surface 66. In accordance with such an embodiment, once the apparatus 100 is mounted to the surface 66, the solar panel 130 will begin generating electrical energy in the presence of sunlight. This energy will then be stored in the storage device 150. When the storage device 150 is sufficiently charged, and when the photosensor 120 detects ambient light conditions below a predetermined level, the storage device will supply electrical energy to the light source 140, which will cause the light source to project light LL.

The photosensor 120 can be adapted to detect ambient light above a predetermined level, in which case the photosensor will accordingly signal the control device 160 to cause the storage device 150 to cease sending electrical energy to the light source 140. Thus, in accordance with at least one embodiment of the present disclosure, the photosensor 120 is adapted to detect ambient light below a predetermined level, wherein the light source 140 is caused to project light 77, and is also adapted to detect ambient light above a predetermined level, wherein the light source is caused to stop projecting light.

The apparatus 100 can be configured such that when the light source 140 projects light 77, the light is directed substantially through the lower side 114 of the housing 110. In accordance with at least one embodiment of the present disclosure, the light 77 projected by the light source 140 can be projected substantially through the opening 115 defined in the lower side 114. It is to be understood that the housing 110 can have alternative configurations not specifically depicted or described herein. By way of example, the housing 110 can be alternatively configured such that rather than defining the opening 115, the lower side 114 can be at least partially transparent and/or translucent in order to allow at least a portion of the light 77 projected by the light source 140 to be projected through the lower side.

It will be noted that the specific shape and/or configuration of the apparatus 100 as well as the location and orientation of the various components thereof can provide associated benefits. For example, the slope or inclination of the upper side 112 can prevent blockage of the solar panel 130 from accumulation or buildup of material and debris. More specifically, the slope of the upper side 112 can promote shedding of such material and debris, while still enabling the solar panel to be exposed to solar radiation as required for operation. The prevention of buildup of material and debris on the solar panel 130 can facilitate higher operating efficiency and output. Additionally, the rounded configuration of the lower side 114 together with the sloping upper side 112 provides a substantially compact, safe, attractive, and strong enclosure for the operating components.

Thus, a method of providing illumination includes providing a housing 110 shaped substantially like a cylindrical wedge and supporting on an upper side 112 of the housing a solar panel 130 adapted to produce electrical power. The method can further include supporting within the housing 110 a light source 140 adapted to produce light from the electrical power produced by the solar panel 130. The housing 110 has a lower side that is adapted to allow the light to be projected substantially through it by way of an opening or the like.

### Interpretation Notes

The above description has set out various features, functions, methods and other aspects of the inventions. This has been done with regard to the currently preferred embodiments thereof. Time and further development may change the manner in which the various aspects are implemented. Such aspects may further be added to by the language of the claims which are incorporated by reference hereinto as originally filed.

The scope of protection accorded the inventions as defined by the claims is not intended to be necessarily limited to the specific sizes, shapes, features or other aspects of the currently preferred embodiments shown and described. The claimed inventions may be implemented or embodied in other forms while still being within the concepts shown, described and claimed herein. Also included are equivalents of the inventions which can be made without departing from the scope of concepts properly protected hereby.

What is claimed is:

1. An apparatus, comprising:
a solar panel adapted to generate electrical power from solar radiation;
a light source adapted to produce light from the electrical power generated by the solar panel; and
a wedge-shaped housing adapted to be mounted on a substantially vertical surface, wherein the lighting system is supported by the housing, the housing comprising:
a substantially flat back adapted to be positioned against the surface;
a substantially flat upper surface angled relative to the back, on which upper surface the solar panel is supported; and
a curved lower surface adapted to allow the light to be projected substantially downwardly there through.

2. The apparatus of claim 1, wherein:
the solar panel is substantially flat; and
the solar panel and the upper side are substantially parallel.

3. The apparatus of claim 1, further comprising a storage device adapted to store the electrical power, and a control device adapted to control flow of electrical power to the light source.

4. The apparatus of claim 1, wherein the housing is substantially shaped like a cylindrical wedge.

5. The apparatus of claim 1, wherein:
the housing is substantially shaped like a cylindrical wedge defined by a generalized cylinder, a base that intersects the generalized cylinder, and a tongue that intersects the generalized cylinder and the base; and
the back of the housing corresponds to the base of the generalized cylinder.

6. The apparatus of claim 1, wherein:
the housing is substantially shaped like a cylindrical wedge defined by a generalized cylinder, a base that intersects the generalized cylinder, and a tongue that intersects the generalized cylinder and the base; and
the upper side of the housing corresponds to the tongue of the generalized cylinder.

7. The apparatus of claim 1, wherein:
the housing is substantially shaped like a cylindrical wedge defined by a generalized cylinder, a base that intersects the generalized cylinder, and a tongue that intersects the generalized cylinder and the base; and
the lower side of the housing corresponds to the generalized cylinder of the cylindrical wedge.

8. The apparatus of claim 1, wherein:
the housing is substantially shaped like a cylindrical wedge defined by a generalized cylinder, a base that intersects the generalized cylinder, and a tongue that intersects the generalized cylinder and the base;
the back of the housing corresponds to the base of the generalized cylinder; and
the upper side of the housing corresponding to the tongue of the generalized cylinder.

9. The apparatus of claim 1, wherein:
the housing is substantially shaped like a cylindrical wedge defined by a generalized cylinder, a base that intersects the generalized cylinder, and a tongue that intersects the generalized cylinder and the base;
the back of the housing corresponds to the base of the cylindrical wedge; and
the lower side of the housing corresponds to the generalized cylinder of the cylindrical wedge.

10. The apparatus of claim 1, wherein:
the housing is substantially shaped like a cylindrical wedge defined by a generalized cylinder, a base that intersects the generalized cylinder, and a tongue that intersects the generalized cylinder and the base;
the upper side of the housing corresponds to the tongue of the cylindrical wedge; and
the lower side of the housing corresponds to the generalized cylinder of the cylindrical wedge.

11. The apparatus of claim 1, wherein:
the housing is substantially shaped like a cylindrical wedge defined by a generalized cylinder, a base that intersects the generalized cylinder, and a tongue that intersects the generalized cylinder and the base;
the back of the housing corresponds to the base of the cylindrical wedge;
the upper side of the housing corresponds to the tongue of the cylindrical wedge; and
the lower side of the housing corresponds to the generalized cylinder of the cylindrical wedge.

12. The apparatus of claim 1, wherein the back, the upper side and the lower side form substantially the whole of the housing.

13. The apparatus of claim 1, wherein upper side and the lower side adjoin each other, and the back adjoins the upper side and the lower side.

14. The apparatus of claim 1, wherein the lower side is substantially normal to the back.

15. The apparatus of claim 1, wherein the back and the upper side are obliquely oriented relative to each other.

16. The apparatus of claim 1, wherein the lower side is substantially circular.

17. An apparatus comprising a solar-powered lighting system supported by a housing shaped substantially like a cylindrical wedge, wherein:
a back of the housing corresponds to a base of the cylindrical wedge;
an upper side of the housing corresponds to a tongue of the cylindrical wedge; and
a lower side of the housing corresponds to a generalized cylinder of the cylindrical wedge.

18. The apparatus of claim 17, the lighting system comprising a substantially flat solar panel supported on and in substantially parallel orientation with the upper side of the housing.

19. The apparatus of claim 17, the lighting system comprising a light source adapted to produce light, the lower side of the housing being adapted to allow the light to be projected there through.

20. A method of providing illumination, comprising:
providing a housing shaped substantially like a cylindrical wedge;
supporting on an upper side of the housing a substantially flat solar panel adapted to produce electrical power from solar radiation, the upper side corresponding to a tongue of the cylindrical wedge;
supporting within the housing a light source adapted to produce light from the electrical power, a lower side of the housing being adapted to allow the light to be projected there through, the lower side corresponding to a generalized cylinder of the cylindrical wedge.
